(19) United States
(12) Patent Application Publication
(10) Pub. No.: US 2025/0048553 A1
(43) Pub. Date: Feb. 6, 2025

(54) PRINTED CIRCUIT BOARD

(71) Applicant: SAMSUNG ELECTRO-MECHANICS CO., LTD., Suwon-si (KR)

(72) Inventors: Tae Hong MIN, Suwon-si (KR); Sang Hoon KIM, Suwon-si (KR)

(73) Assignee: SAMSUNG ELECTRO-MECHANICS CO., LTD., Suwon-si (KR)

(21) Appl. No.: 18/746,534

(22) Filed: Jun. 18, 2024

(30) Foreign Application Priority Data
Aug. 1, 2023 (KR) 10-2023-0100479

(51) Int. Cl. H05K 1/14; H05K 1/18

(52) U.S. Cl. CPC H05K 1/144; H05K 1/142; H05K 1/181; H05K 2201/041; H05K 2201/10416; H05K 2201/10462; H05K 2201/10522

(57) ABSTRACT

A printed circuit board includes a first substrate portion including a first insulating portion and a plurality of first wiring layers respectively disposed on or in the first insulating portion, a resin layer disposed to cover a side surface of the first insulating portion, and a second substrate portion including a second insulating portion disposed to cover each of an upper surface of the first insulating portion and an upper surface of the resin layer, and a second wiring layer disposed on or in the second insulating portion.

### CROSS-REFERENCE TO RELATED APPLICATION(S)

This application claims benefit of priority to Korean Patent Application No. 10-2023-0100479 filed on Aug. 1, 2023 in the Korean Intellectual Property Office, the disclosure of which is incorporated herein by reference in its entirety.

### TECHNICAL FIELD

The present disclosure relates to a printed circuit board.

Multichip packages including a memory chip such as a high bandwidth memory (HBM) and a processor chip such as a central processing unit (CPU), a graphics processing unit (GPU), an application specific integrated circuit (ASIC), or a field programmable gate array (FPGA) have been used to process data, exponentially increasing due to recent developments in artificial intelligence (AI) technology. In order for various chips to be mounted on a board, research has been conducted to implement fine circuits more stably on the board, to prevent defects occurring in an operation of manufacturing the board, and to improve yield.

### SUMMARY

An aspect of the present disclosure provides a printed circuit board on which an electronic component and a chip are mounted, the printed circuit board capable of preventing defects occurring therein, the printed circuit board having improved yield.

Another aspect of the present disclosure provides a printed circuit board having improved heat dissipation characteristics.

Another aspect of the present disclosure provides a method for manufacturing a printed circuit board having improved reliability.

According to an aspect of the present disclosure, there is provided a printed circuit board including a first substrate portion including a first insulating portion and a plurality of first wiring layers respectively disposed on or in the first insulating portion, a resin layer disposed to cover a side surface of the first insulating portion, and a second substrate portion including a second insulating portion disposed to cover each of an upper surface of the first insulating portion and an upper surface of the resin layer, and a second wiring layer disposed on or in the second insulating portion.

According to another aspect of the present disclosure, there is provided a printed circuit board including a first substrate portion including a first insulating portion and a first wiring layer disposed on or in the first insulating portion, a resin layer disposed to cover a side surface of the first substrate portion, and a second substrate portion including a second insulating portion disposed on the first insulating portion and the resin layer, and a second wiring layer disposed on or in the second insulating portion. An upper surface of the resin layer may be substantially coplanar with an upper surface of the first insulating portion.

According to another aspect of the present disclosure, there is provided a printed circuit board including a first substrate portion including a first insulating portion and a first wiring layer disposed on or in the first insulating portion; a resin layer disposed to cover a side surface of the first substrate portion; a second substrate portion including a second insulating portion disposed on the first insulating portion and the resin layer, and a second wiring layer disposed on or in the second insulating portion; and a third substrate portion including a third insulating portion disposed on a lower side of the first insulating portion, and a third wiring layer disposed on the third insulating portion. A lower surface of the resin layer may be substantially coplanar with a lower surface of the third wiring layer.

According to example embodiments of the present disclosure, a printed circuit board on which an electronic component and a chip are mounted may prevent defects occurring therein, and may have improved yield.

The printed circuit board may have improved heat dissipation characteristics.

The printed circuit board may have improved reliability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating a printed circuit board according to an example;

FIGS. 4A and 4B are schematic cross-sectional views illustrating a printed circuit board according to another example;

FIGS. 5A and 5B are schematic cross-sectional views illustrating a printed circuit board according to another example; and

FIGS. 6A to 6H are cross-schematic cross-sectional views illustrating a method for manufacturing a printed circuit board according to an example.

### DETAILED DESCRIPTION

Hereinafter, the present disclosure will be described with reference to the accompanying drawings. The shapes and sizes of components in the drawings may be exaggerated or reduced for clearer description.

### Electronic Device

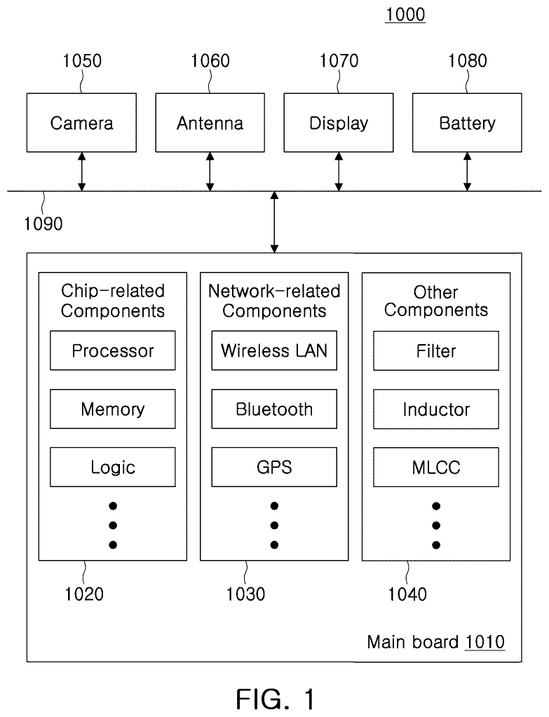

FIG. 1 is a schematic block diagram illustrating an example of an electronic device system.

Referring to FIG. 1, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an m analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may have the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

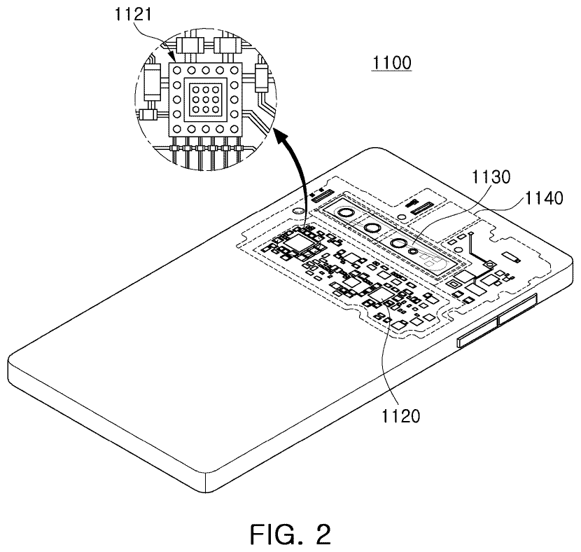

FIG. 2 is a schematic perspective view illustrating an example of an electronic device.

Referring to FIG. 2, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may have the form of a printed circuit board on which electronic components including active components and/or passive components are surface-mounted. The electronic device is not necessarily limited to the smartphone 1100, and may be other electronic devices, as described above.

### Printed Circuit Board

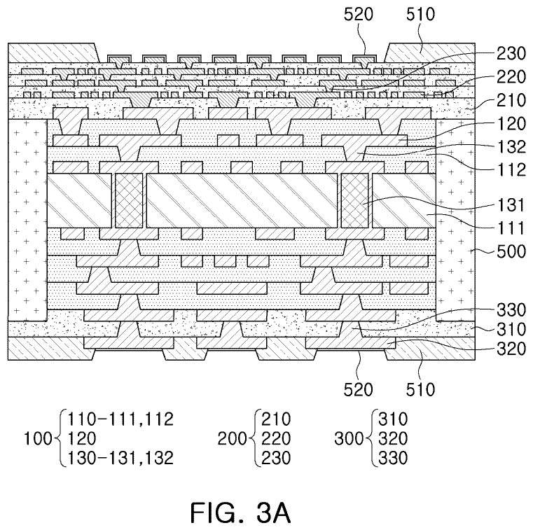

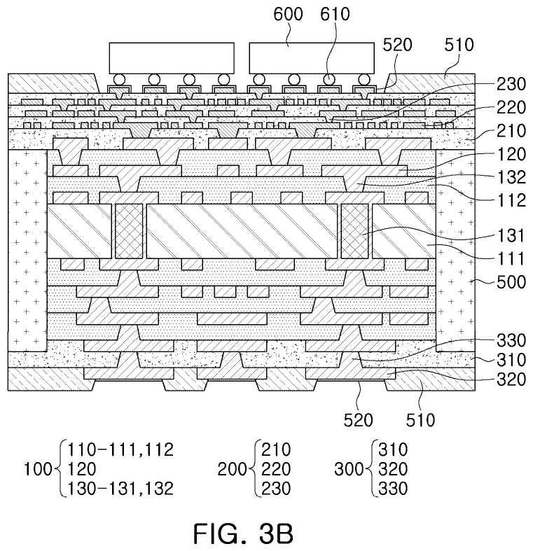

FIGS. 3A and 3B are schematic cross-sectional views illustrating a printed circuit board according to an example.

Referring to FIG. 3A, the printed circuit board according to an example may include a first substrate portion 100, a second substrate portion 200, and a resin layer 500. The first substrate portion 100 may include a first insulating portion 110 and a plurality of first wiring layers 120 respectively disposed on or in the first insulating portion 110, and the second substrate portion 200 may include a second insulating portion 210, and a second wiring layer 220 disposed on or in the second insulating portion 210.

The first substrate portion 100 may be a portion implementing a signal path of the printed circuit board, and the second substrate portion 200 may be a portion connecting the first substrate portion 100 and a component disposed on the printed circuit board to each other. The second substrate portion 200 may be a portion implementing a fine signal path, and may be a portion serving as a buffer against a fine pad when a component, such as a semiconductor chip, is mounted. That is, the second substrate portion 200 may be a portion for stably maintaining a component, such as a chip relatively finer than that of the first substrate portion 100, and an electrical signal path.

The first insulating portion 110 of the first substrate portion 100 may include a plurality of insulating layers. More specifically, the first insulating portion 110 may include a core layer 111 disposed on a central portion thereof, and a plurality of build-up insulating layers 112 disposed on the core layer 111. The plurality of first wiring layers 120 may be disposed on the core layer 111 and buried by a build-up insulating layer 112, or may be disposed on the build-up insulating layer 112 and buried by another build-up insulating layer 112. However, the present disclosure is not limited thereto, and the first substrate portion 100 may have a coreless board structure not including the core layer 111.

The core layer 111 may include an insulating material. The insulating material may include a thermosetting resin such as an epoxy resin, a thermoplastic resin such as a polyimide, or a material including an inorganic filler, organic filler, and/or glass fiber (glass cloth, and/or glass fabric), together with such resins. The insulating material may be a photosensitive material and/or a non-photosensitive material. The insulating material may be a solder resist, an Ajinomoto build-up film (ABF), FR-4, bismaleimide triazine (BT), an insulating material such as resin coated copper (RCC), an insulating material such as a copper clad laminate (CCL), and the like, but the present disclosure is not limited thereto, and may include other polymeric materials. The insulating material may include the above-described resins including reinforcing materials such as an inorganic filler, such as silica, and a glass fiber. For example, a prepreg may be used, but the present disclosure not limited thereto. In addition, in FIG. 3A, the core layer 111 is illustrated as a single layer, but the present disclosure is not limited thereto, and a plurality of thin cores may be stacked to form the core layer 111.

The build-up insulating layer 112 may include an insulating material. The insulating material of the build-up insulating layer 112 may be selected from the same group of insulating materials as the insulating materials of the core layer 111, but the present disclosure is not limited thereto. Any material that could be used as an insulating material for a printed circuit board may be selected. For example, the insulating material of the build-up insulating layer 112 may be an insulating resin including reinforcing materials such as an inorganic filler, such as silica, and a glass fiber. Specifically, a prepreg may be used, but the present disclosure is not limited thereto, and the insulating material may include an ABF. The build-up insulating layer 112 may include a plurality of insulating layers, and each build-up insulating layer 112 may include the same insulating material, but the present disclosure is not limited thereto, and may include different materials.

In FIGS. 3A and 3B, it is illustrated that two build-up insulating layers 112 are disposed on an upper side of the core layer 111, and three build-up insulating layers 112 are disposed on a lower side of the core layer 111. Such a configuration may be advantageous in preventing warpage caused by asymmetry in an operation of forming the second substrate portion 200 on the first substrate portion 100. However, the present disclosure is not necessarily limited thereto, and the number of build-up insulating layers 112 may be disposed to be symmetrical to each other with respect to the core layer 111. In addition, the present disclosure is not limited thereto, and the number of build-up insulating layers 112 may vary depending on the purpose and design of a board, and may be used without limitation.

The first substrate portion 100 of the printed circuit board according to an example may include a plurality of first wiring layers 120. A portion of the plurality of first wiring layers 120 may be disposed on the core layer 111, and the other portion may be disposed on the build-up insulating layer 112. The present disclosure is not limited thereto, and the first wiring layer 120 may not be disposed on the core layer 111, and the first wiring layer 120 may be disposed only on the build-up insulating layer 112. The number of the plurality of first wiring layers 120 of the first substrate portion 100 is not limited, and may correspond to the number of build-up insulating layers 112.

Each of the plurality of first wiring layers 120 may include a metal material. The metal material may include copper (Cu), aluminum (Al), silver (Ag), tin (Sn), gold (Au), nickel (Ni), lead (Pb), titanium (Ti), and/or alloys thereto, and may preferably include copper (Cu), but the present disclosure is not limited thereto. Each circuit pattern may be a circuit pattern for a general signal path, and may perform various functions depending on the design thereof, such as having a component mounted thereon. For example, the circuit pattern may include a ground pattern, a power pattern, a signal pattern, and the like. Here, the signal pattern may refer to including a pattern for electrical connection of various signals other than ground signals, power signals, and the like, for example, data signals. Each of the plurality of first wiring layers 120 may be formed of a plurality of circuit patterns, may be formed of a metal plate, or may be formed of a plurality of circuit patterns and a metal plate together.

Each of the plurality of first wiring layers 120 may be formed using one of a semi-additive process (SAP), a modified semi-additive process (MSAP), tenting (TT), or a subtractive process, but the present disclosure is not limited thereto, and any method capable of forming a circuit pattern in a printed circuit board may be used without limitation. In addition, the plurality of first wiring layers 120 may be formed using different methods depending on the purpose and design thereof.

The first substrate portion 100 of the printed circuit board according to an example may include a plurality of first via layers 130 passing through at least a portion of the first insulating portion 110 to connect the plurality of first wiring layers 120 to each other. The plurality of first via layers 130 may include a through-via 131 and a build-up via layer 132. Passing through at least a portion of the first insulating portion 110 may mean passing through one build-up insulating layer 112 of the first insulating portion 110, or that the first via layer 130 may be formed to pass through a plurality of build-up insulating layers 112 at once.

The through-via 131 may include a metal layer formed on a wall surface of a through-hole passing through the core layer 111, and a plug filling the metal layer. The metal layer may include copper (Cu), aluminum (Al), silver (Ag), tin (Sn), gold (Au), nickel (Ni), lead (Pb), titanium (Ti), or alloys thereof, and may preferably include copper (Cu), but the present disclosure not limited thereto. The plug may include ink formed of an insulating material. The metal layer may include an electroless plating layer (or chemical copper) and an electrolytic plating layer (or electrolytic copper), but the present disclosure not limited thereto. A sputtering layer may be formed instead of the electroless plating layer, and both may be included. The through-via 131 may perform various functions depending on the design thereof. For example, a ground via, a power via, a signal via, and the like may be included.

A plurality of build-up via layers 132 may include a micro via. The micro via may be a filled via filling a via hole, or a conformal via disposed along a wall surface of the via hole. The micro via may be disposed as a stacked type and/or a staggered type. Each of the plurality of build-up via layers 132 may include a metal. The metal may include copper (Cu), aluminum (Al), silver (Ag), tin (Sn), gold (Au), nickel (Ni), lead (Pb), titanium (Ti), or alloys thereof, and may preferably include copper (Cu), but the present disclosure is not limited thereto. Each of the plurality of build-up via layers 132 may include an electroless plating layer (or chemical copper) and an electrolytic plating layer (or electrolytic copper), but the present disclosure is not limited thereto. A sputtering layer may be formed instead of the electroless plating layer, and both may be included. The plurality of build-up via layers 132 may perform various functions depending on the design of a corresponding layer. For example, a ground via, a power via, a signal via, and the like may be included.

As described above, the number of build-up insulating layers 112 of the first insulating portion 110 and the number of the plurality of first wiring layers 120 may not be limited. Accordingly, the number of layers of a via, a component passing through at least a portion of the first insulating portion 110 to connect the plurality of first wiring layers 120 to each other, may not be limited.

In FIG. 3A, the first substrate portion 100 is illustrated as including a first insulating portion 110, a first wiring layer 120, and a first via layer 130, but the present disclosure is not limited thereto, and may further include a cavity passing through at least a portion of the first insulating portion 110, and may further include a technology or component that may be used by those skilled in the art, such as a board with embedded electronic components, or the like.

The second substrate portion 200 of the printed circuit board according to an example may include a second insulating portion 210, and a second wiring layer 220 disposed on or in the second insulating portion 210. As the second substrate portion 200 is disposed on the first substrate portion 100, the second insulating portion 210 may cover an upper surface of the first insulating portion 110, and the second insulating portion 210 may cover at least a portion of the first wiring layer 120. That is, the second insulating portion 210 may cover at least a portion of an uppermost first wiring layer 120, among the plurality of first wiring layers 120.

The second insulating portion 210 may include a plurality of insulating layers. Each of the plurality of insulating layers of the second insulating portion 210 may include an insulating material. The insulating material may include a thermosetting resin such as an epoxy resin, a thermoplastic resin such as a polyimide, or a material including an inorganic filler, organic filler, and/or glass fiber (glass cloth, and/or glass fabric), together with such resins. The insulating material may be a photosensitive material and/or a non-photosensitive material. The insulating material may be a solder resist, an ABF, FR-4, BT, an insulating material such as RCC, an insulating material such as a CCL, and the like, but the present disclosure is not limited thereto, and may include other polymeric materials. The insulating material may include the above-described resins including reinforcing materials such as an inorganic filler, such as silica, and a glass fiber. For example, a prepreg may be used, but the present disclosure not limited thereto, and the ABF or the photosensitive material may be included. The plurality of insulating layers of the second insulating portion 210 may include substantially the same insulating material, but the present disclosure is not limited thereto, and may include different materials.

The second substrate portion 200 may include an insulating material that is more advantageous for microfabrication than the first insulation portion 110 to implement a wiring finer than that of the first substrate portion 100. For example, a content of reinforcing materials such as an inorganic filler and a glass fiber included in each insulating layer of the second insulating portion 210 may be greater than a content of reinforcing materials such as an inorganic filler and a glass fiber included in the build-up insulating layer 112 of the first insulating portion 110. A content of reinforcing materials, such as an inorganic filler and a glass fiber, of an insulating material of the second insulating portion 210 may be allowed to be greater than a content of reinforcing materials of an insulating material of the first insulating portion 110, thereby implementing an insulating layer advantageous for microfabrication. However, the present disclosure is not necessarily limited thereto, and the second insulating portion 210 of the second substrate portion 200 and the first insulating portion 110 of the first substrate portion 100 may include substantially the same insulating material. In addition, the present disclosure is not limited thereto, and the second insulating portion 210 may include a photosensitive material, which may be more advantageous for microfabrication than forming a wiring in the first insulating portion 110.

In FIG. 3A, the second insulating portion 210 is illustrated as including four insulating layers, but the number of insulating layers of the second insulating portion 210 is not limited thereto, and may vary depending on the purpose and design of a board, and may be used without limitation.

The second substrate portion 200 of the printed circuit board according to an example may include a plurality of second wiring layers 220. Each of the plurality of second wiring layers 220 may be disposed on or in the second insulating portion 210. The plurality of second wiring layers 220 may be disposed on one insulating layer of the second insulating portion 210 and buried in another insulating layer, or may be disposed on one insulating layer and externally exposed. The number of the plurality of second wiring layers 220 of the second substrate portion 200 is not limited, and may correspond to the number of insulating layers of the second insulating portion 210.

Each of the plurality of second wiring layers 220 may include a metal material. The metal material may include copper (Cu), aluminum (Al), silver (Ag), tin (Sn), gold (Au), nickel (Ni), lead (Pb), titanium (Ti), and/or alloys thereto, and may preferably include copper (Cu), but the present disclosure is not limited thereto. Each of the plurality of second wiring layers 220 may be a circuit pattern for a general signal path, and may perform various functions depending on the design thereof, such as having a component mounted thereon. For example, the circuit pattern may include a ground pattern, a power pattern, a signal pattern, and the like. Here, the signal pattern may refer to including a pattern for electrical connection of various signals other than ground signals, power signals, and the like, for example, data signals. Each of the plurality of second wiring layers 220 may be formed of a plurality of circuit patterns, may be formed of a metal plate, or may be formed of a plurality of circuit patterns and a metal plate together.

Each of the plurality of second wiring layers 220 may be formed using one of a semi-additive process (SAP), a modified semi-additive process (MSAP), tenting (TT), or a subtractive process, but the present disclosure is not limited thereto, and any method capable of forming a circuit in a printed circuit board may be used without limitation. In addition, the plurality of second wiring layers 220 may be formed using different methods depending on the purpose and design thereof.

The second substrate portion 200 of the printed circuit board according to an example may include a plurality of second via layers 230 passing through at least a portion of the second insulating portion 210 to connect the plurality of second wiring layers 220 to each other. Passing through at least a portion of the second insulating portion 210 may mean passing through one insulating layer of the second insulating portion 210, or that a second via layer 230 may be formed to pass through a plurality of insulating layers of the second insulating portion 210 at once. However, the present disclosure is not limited thereto, and one via layer, among the plurality of second via layers 230, may pass through at least a portion of the second insulating portion 210 to connect a second wiring layer 220, disposed on a lowermost side of the second substrate portion 200, and a first wiring layer 120, disposed on an uppermost side of the first substrate portion 100, to each other.

The plurality of second via layers 230 may include a micro via. The micro via may be a filled via filling a via hole, or a conformal via disposed along a wall surface of the via hole. The micro via may be disposed as a stacked type and/or a staggered type. Each of the plurality of build-up via layers 132 may include a metal. The metal may include copper (Cu), aluminum (Al), silver (Ag), tin (Sn), gold (Au), nickel (Ni), lead (Pb), titanium (Ti), or alloys thereof, and may preferably include copper (Cu), but the present disclosure is not limited thereto. Each of the plurality of second via layers 230 may include an electroless plating layer (or chemical copper) and an electrolytic plating layer (or electrolytic copper), but the present disclosure is not limited thereto. A sputtering layer may be formed instead of the electroless plating layer, and both may be included. The plurality of second via layers 230 may perform various functions depending on the design of a corresponding layer. For example, a ground via, a power via, a signal via, and the like may be included.

As described above, the number of insulating layers of the second insulating portion 210 and the number of the plurality of second wiring layers 220 may not be limited. Accordingly, the number of layers of a via, a component passing through at least a portion of the second insulating portion 210 to connect the plurality of second wiring layers 220 to each other, may not be limited.

The second wiring layer 220 of the second substrate portion 200 may have a wiring density higher than that of the first wiring layer of the first substrate portion 100. That is, the second wiring layer 220 may include a wiring finer than an wiring of the first wiring layer 120. Higher wiring density may be based on a relative concept, and may mean, for example, that an average pitch of a wiring included in the second wiring layer 220 may be lower than an average pitch of an wiring included in the first wiring layer 120. A pitch may be measured by photographing a cut cross-section of the printed circuit board using a scanning microscope, and an average pitch may be an average of values of a pitch between wirings measured at any five points. In addition, an average interlayer insulation distance between the second wiring layers 220 may be less than an average interlayer insulation distance between the plurality of first wiring layers 120. The interlayer insulation distance may also be measured by photographing a cut cross-section of the printed circuit board using a scanning microscope, and the average interlayer insulation distance may be an average of values of an insulation distance between adjacent wiring layers measured at any five points. That is, the wiring included in the second wiring layer 220 may be a high-density fine wiring having a line/space (L/S) smaller than that of the wiring included in the first wiring layer 120. As a non-limiting example, the line/space of the wiring included in the second wiring layer 220 may be about 2/2 μm, but the present disclosure is not limited thereto. As the second wiring layer 220 of the second substrate portion 200 has a high wiring density, it may be effective when electronic components such as semiconductor chips are connected to each other. That is, the second substrate portion 200 may be used as a redistribution layer of a semiconductor chip.

The printed circuit board according to an example may include a resin layer 500 disposed on a side surface of the first substrate portion 100. The resin layer 500 may be disposed to cover a side surface of the first insulating portion 110, and may be disposed on a lower surface of the second insulating portion 210. That is, an upper surface of the resin layer 500 may be covered by the second insulating portion 210. In other words, the second insulating portion 210 of the second substrate portion 200 may cover an upper surface of the first insulating portion 110 of the first substrate portion 100 and an upper surface of the resin layer 500.

The resin layer 500 may be disposed on a side surface of the first substrate portion 100 after the first substrate portion 100 is completed, and may perform a function of supporting the first substrate portion 100. The second substrate portion 200 may be formed on the first substrate portion 100 and the resin layer 500, such that the above-described arrangement may be achieved. After the first substrate portion 100 is completed, when it is possible to determine a defect in the first substrate portion 100 before the resin layer 500 is coupled to a side surface of the first substrate portion 100, a defect rate of the printed circuit board may be reduced. When the second substrate portion 200 is formed immediately after the first substrate portion 100 is formed, a defect in the printed circuit board may be a defect occurring in the first substrate portion 100 or a defect occurring in the second substrate portion 200. Accordingly, manufacturing the second substrate portion 200, implementing a fine wiring on the first substrate portion 100 in which a defect has already occurred, may be a waste of cost. In the printed circuit board according to an example, the second substrate portion 200 may be formed using only the first substrate portion 100 in which no defect has occurred, after the first substrate portion 100 is completed and it is determined whether there is a defect. Accordingly, a defect in the printed circuit board may be controlled by controlling a defect in the second substrate portion 200. That is, a case may be excluded in which a defect occurs in the printed circuit board due to the high-quality second substrate portion 200 formed on the defective first substrate portion 100. Accordingly, even when the printed circuit board according to an example is manufactured in a single unit of a strip using a singulation process, the first substrate portion 100 may be first manufactured, and then a jig J may be inserted to fill the resin layer 500, thereby reducing the defect rate and minimizing costs.

The resin layer 500 may include an organic material, and the organic material may include at least one of a thermal interface material (TIM), a bonding sheet, an epoxy molding compound (EMC), or an underfill resin, but the present disclosure is not limited thereto, and any material capable of coupling and fixing the first substrate portion 100 to the temporary jig J may be used without limitation. When the resin layer 500 includes a TIM having excellent heat dissipation characteristics, the printed circuit board may have improved overall heat dissipation characteristics of, and heat generated in an electronic component, such as a semiconductor chip disposed on the second substrate portion 200, may be effectively dissipated to the outside.

An outermost portion of a side surface of the printed circuit board according to an example may include the resin layer 500. That is, a side surface of the resin layer 500 may be exposed to the outside of the printed circuit board. Conversely, the first insulating portion 110 may be covered by the resin layer 500, such that a side surface of the first insulating portion 110 may not be exposed to the outside of the printed circuit board. In addition, a side surface of the second insulating portion 210 may be substantially coplanar with the side surface of the resin layer 500. Being substantially coplanar is based on a concept including being approximately coplanar. In one example, the term “substantially” may refer to a concept including a minute difference caused by a process error or a measurement error. For example, “being substantially coplanar” may include not only a case of being “coplanar”, but also a case of having a minute difference caused by a process error or a measurement error, recognizable by one of ordinary skill in the art. When the second substrate portion 200 is cut to pass through the resin layer 500 for singulation after the second substrate portion 200 is formed on the resin layer 500 in a manufacturing operation, the resin layer 500 may be disposed on an outermost side of the printed circuit board, such that the side surface of the resin layer 500 may be coplanar with the second insulating portion 210 of the second substrate portion 200. When the resin layer 500 has excellent heat dissipation characteristics, a more advantageous effect in heat dissipation may be obtained due to the resin layer 500 disposed on the outermost side of the printed circuit board. The present disclosure is not limited thereto, and the resin layer 500 may include a material having excellent rigidity to ensure the rigidity of the printed circuit board. The present disclosure is not limited thereto, and the resin layer 500 may prevent the first insulating portion 110 from scattering during the singulation process of the printed circuit board.

At least a portion of the second wiring layer 220 may be disposed on an upper region of the resin layer 500. In an operation of manufacturing the printed circuit board, the resin layer 500 may be disposed on a side surface of the first substrate portion 100, and then the second substrate portion 200 may be formed on the first substrate portion 100 and the resin layer 500, such that the second substrate portion 200 may be formed across the first substrate portion 100 and the resin layer 500. An area of the second substrate portion 200 may be wider than an area of the first substrate portion 100, and a difference in area may be an area corresponding to that of the resin layer 500. Accordingly, the second wiring layer 220 of the second substrate portion 200 may be formed over a wider area, making it possible to increase the area of the second substrate portion 200. The present disclosure is not limited thereto, and the second wiring layer 220 may be formed only in the first substrate portion 100.

The printed circuit board according to an example may further include a third substrate portion 300 disposed on a lower side of the first insulating portion 110 of the first substrate portion 100. The third substrate portion 300 may include a third insulating portion 310 and a third wiring layer 320 disposed on the third insulating portion 310, and may include a third via layer 330 passing through at least a portion of the third insulating portion 310 to connect the third wiring layer 320 and the first wiring layer 120 to each other.

The third insulating portion 310 may include a material substantially the same as that of the second insulating portion 210. The third insulating portion 310 may be formed at the same time as the second insulating portion 210 is formed. As the third insulating portion 310 is formed at the same time as the second insulating portion 210, warpage occurring in an operation of manufacturing the printed circuit board according to an example may be controlled.

The third wiring layer 320 may be disposed on a lowermost side of the printed circuit board, and may function as a pad such that a lower surface of the printed circuit board is connected to other components, and the third via layer 330 may perform a function of connecting the third wiring layer 320 and the first wiring layer 120 to each other, but the present disclosure is not limited thereto. The third wiring layer 320 and/or the third via layer 330 may include a metal material, and the metal material may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure is not limited thereto.

A portion of the resin layer 500 may be buried in the third insulating portion 310. That is, a lower surface of the resin layer 500 may be covered by the third insulating portion, and a portion of a side surface of the resin layer 500 may be covered by the third insulating portion. Such a structure may be a structure according to an operation of manufacturing the printed circuit board, and will be described in detail below in a method for manufacturing the printed circuit board.

The printed circuit board according to an example may further include a solder resist layer 510 disposed on the second insulating portion 210 and/or the third insulating portion 310. The solder resist layer 510 may be disposed on an outermost side of the printed circuit board to protect the printed circuit board from the outside. The solder resist layer 510 may use a known solder resist, and the solder resist layer 510 may include a thermosetting resin and an inorganic filler dispersed in the thermosetting resin, but may not include a glass fiber. An insulating resin may be a photosensitive insulating resin, and a filler may be an inorganic filler and/or an organic filler, but the present disclosure is not limited thereto, and other polymer materials may be used, as necessary. The solder resist layer 510 may have an opening, and at least a portion of the second wiring layer 220 and at least a portion of the third wiring layer 320 may be exposed through the opening. The second wiring layer 220 exposed through the opening may be connected to another device such as a semiconductor chip, and the third wiring layer 320 exposed through the opening may be connected to a main board or another printed circuit board, and may also be connected to another device such as a semiconductor chip.

The printed circuit board according to an example may further include a surface treatment layer 520 covering an exposed region of the second wiring layer 220 and/or covering an exposed region of the third wiring layer 320. The surface treatment layer 520 may include one of nickel (Ni), palladium (Pd), and gold (Au), and a plurality of layers, formed of the above-described metals, may be implemented. The surface treatment layer 520 may be formed using an ENIG or ENEPIG method, but the present disclosure is not limited thereto. The surface treatment layer may include an organic substance. The surface treatment layer 520 may improve bonding force and signal transmission force of a wiring layer, functioning as a pad of the printed circuit board, and a component mounted on the printed circuit board.

Referring to FIG. 3B, the printed circuit board according to an example may further include a semiconductor chip 600 disposed on the second substrate portion 200, and a connection member 610 for connecting the semiconductor chip 600 and the second wiring layer 220 of the second substrate portion 200 to each other.

Each of the semiconductor chips 600 may include an integrated circuit (IC) die in which hundreds to millions of devices are integrated into a single chip. In this case, the IC may be, for example, a logic chip such as a central processor (for example, a CPU), a graphics processing unit (for example, a GPU), a field programmable gate array (FPGA), a digital signal processor, a cryptographic processor, a microprocessor, a microcontroller, an application processor (for example, an AP), an analog-to-digital converter, or an application-specific IC (ASIC), but the present disclosure is not limited thereto, and may also be a memory chip such as a volatile memory (for example, a DRAM), a non-volatile memory (for example, a ROM), a flash memory, or a high bandwidth memory (HBM), or a power management IC (PMIC). Alternatively, the semiconductor chip 600 may be divided logic chips, divided by die split, the divided logic chips having different cores.

Each of the semiconductor chips 600 may be formed based on an active wafer. In this case, silicon (Si), germanium (Ge), gallium arsenide (GaAs), and the like may be used as base materials included in respective bodies. Various circuits may be formed in the body. A connection pad may be formed on each body, and the connection pad may include a conductive material such as aluminum (Al) or copper (Cu). The semiconductor chip may be a bare die. In this case, a metal bump may be disposed on the connection pad. The semiconductor chip may be a packaged die. In this case, a redistribution layer may be additionally formed on the connection pad, and a metal bump may be disposed on the redistribution layer.

The connection member 610 may be formed of a low melting point metal, for example, solder such as tin (Sn)-aluminum (Al)-copper (Cu), but the present disclosure is not limited thereto. The connection member 610 may be formed as multiple layers or a single layer. When formed as multiple layers, the connection member 610 may include a copper pillar and solder. When formed as a single layer, the connection member 610 may include tin-silver solder or copper, but the present disclosure is not limited thereto. In addition, any means, serving as an intermediary to electrically connect a semiconductor chip or electronic component to the second wiring layer 220 of the second substrate portion 200, may be used without limitation. In FIG. 3B, two semiconductor chips are illustrated as being mounted, but the present disclosure is not limited thereto. A larger number of semiconductor chips may be mounted, and a larger or smaller number of semiconductor chips 600 may also be electrically connected to each other by the connection member 610.

The printed circuit board according to an example is not limited to the components illustrated in FIGS. 3A and 3B, and may further include a general component of a printed circuit board. That is, the printed circuit board may further include a component that could be used by those skilled in the art.

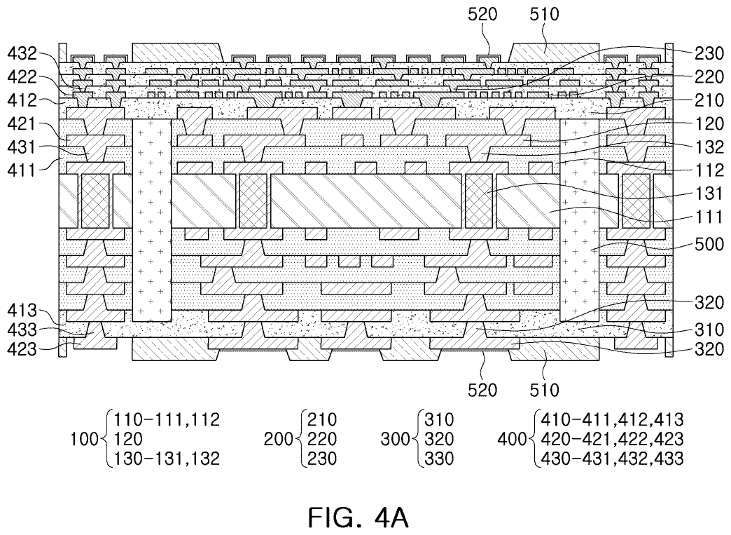

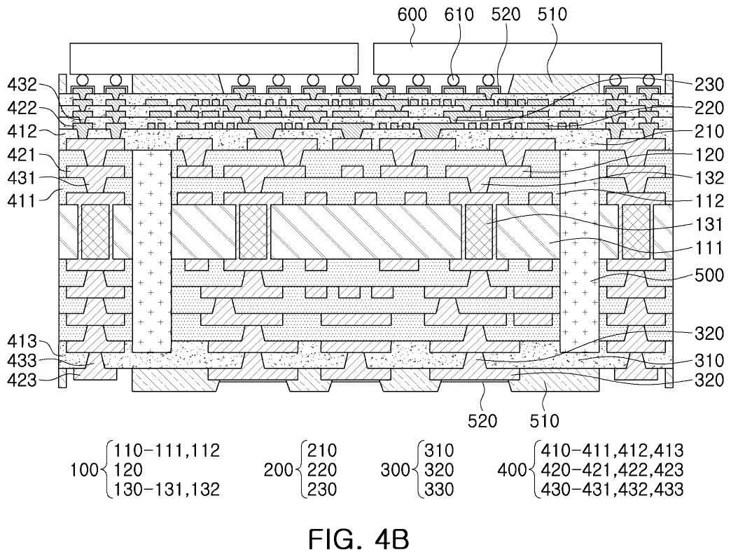

FIGS. 4A and 4B are schematic cross-sectional views illustrating a printed circuit board according to another example.

Referring to FIGS. 4A and 4B, the printed circuit board according to another example may further include a fourth substrate portion 400. The fourth substrate portion 400 may include a fourth insulating portion 410 disposed on side surfaces of first to third insulating portions 110, 210, and 310, a fourth wiring layer 420 disposed on or in the fourth insulating portion, and a fourth via layer 430 passing through at least a portion of the fourth insulating portion 410 to connect the fourth wiring layers 420 to each other.

The fourth insulating portion 410 may include a fourth-first insulating portion 411, a fourth-second insulating portion 412, and a fourth-third insulating portion 413. The fourth-first insulating portion 411 may correspond to the first insulating portion 110, the fourth-second insulating portion 412 may correspond to the second insulating portion 210, and the fourth-third insulating portion 413 may correspond to the third insulating portion 310.

The fourth wiring layer 420 may include a fourth-first wiring layer 421, a fourth-second wiring layer 422, and a fourth-third wiring layer 423. The fourth-first wiring layer 421 may correspond to a first wiring layer 120, the fourth-second wiring layer 422 may correspond to a second wiring layer 220, and the fourth-third wiring layer 423 may correspond to a third wiring layer 320.

The fourth via layer 430 may include a fourth-first via layer 431, a fourth-second via layer 432, and a fourth-third via layer 433. The fourth-first via layer 431 may correspond to a first via layer 130, the fourth-second via layer 432 may correspond to a second via layer 230, and the fourth-third via layer 433 may correspond to a third via layer 330.

One component of the fourth substrate portion 400 corresponding to one component of the first to third substrate portions 100, 200, and 300 may mean that the one component of the fourth substrate portion 400 includes a material substantially the same as the one component of the third substrate portions 100, 200, and 300, includes layers the same number of layers as those of the one component of the first to third substrate portions 100, 200, and 300, has a thickness or density substantially the same that of the one component of the third substrate portions 100, 200, and 300, or may be formed in an operation the same as that of the one component of the third substrate portions 100, 200, and 300. For example, the fourth-first insulating portion 411 that may correspond to the first insulating portion 110 may mean that components of the fourth-first insulating portion 411 may be the same as those of the first insulating portion 110, and may mean that the fourth-first insulating portion 411 may include a core layer 111 and a build-up insulating layer 112, and may have the same number of layers. Such a configuration may be applied to the second substrate portion 200 or the third substrate portion 300 in the same manner, and may be applied not only to an insulating portion but also to a wiring layer or via layer. For example, the fourth-first wiring layer 421 may have a wiring having a density substantially the same as that of an wiring of the first wiring layer 120, and the fourth-second wiring layer 422 may have an wiring having a density substantially the same as that of an wiring of the second wiring layer 220.

The fourth substrate portion 400 may be disposed on a side surface of a resin layer 500, and may be disposed on side surfaces of the second substrate portion 200 and the third substrate portion 300. However, the fourth substrate portion 400 may not have clear boundaries with the second board 200 and the third substrate portion 300, and the fourth substrate portion 400 may be understood as one region of the printed circuit board, not a separately formed board component. In an operation of forming the first substrate portion 100, a portion of the fourth substrate portion 400 may be formed. In an operation of forming the second substrate portion 200, another portion of the fourth substrate portion 400 may be formed. In an operation of forming the third substrate portion 300, the other portion of the fourth substrate portion 400 may be formed. A detailed description thereof will be provided below in connection with a method for manufacturing a printed circuit board.

The fourth substrate portion 400 may perform a heat dissipation function. The fourth insulating portion 410, the fourth wiring layer 420, and the fourth via layer 430 may be disposed such that heat transmitted through an uppermost wiring layer, among the fourth-second wiring layers 422, is dissipated to a lowermost side of the printed circuit board. That is, referring to FIG. 4B, heat generated in a semiconductor chip 600 may be discharged to the lowermost side of the printed circuit board through the fourth substrate portion 400. As the fourth substrate portion 400 is disposed to perform a heat dissipation function, the printed circuit board may have improved heat dissipation characteristics without changing internal designs of the first to third substrate portions 100, 200, and 300. As the fourth substrate portion 400 is disposed to correspond to the first to third substrate portions 100, 200, and 300, the printed circuit board may have enhanced warpage characteristics. In this case, the fourth substrate portion 400 may perform a heat dissipation function, together with the resin layer 500. In this case, a heat dissipation effect may be further increased.

A component the same as that of the printed circuit board according to an example, among components other than the fourth substrate portion 400, may be applied to the printed circuit board according to another example, and thus a repeated description related thereto will be omitted.

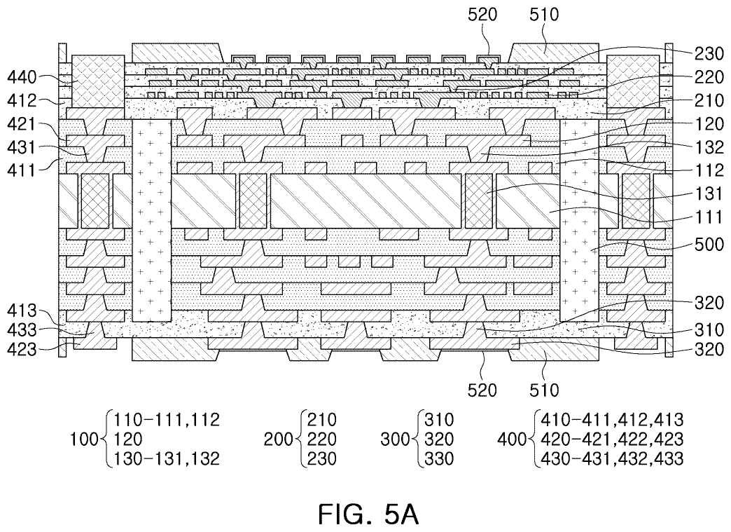

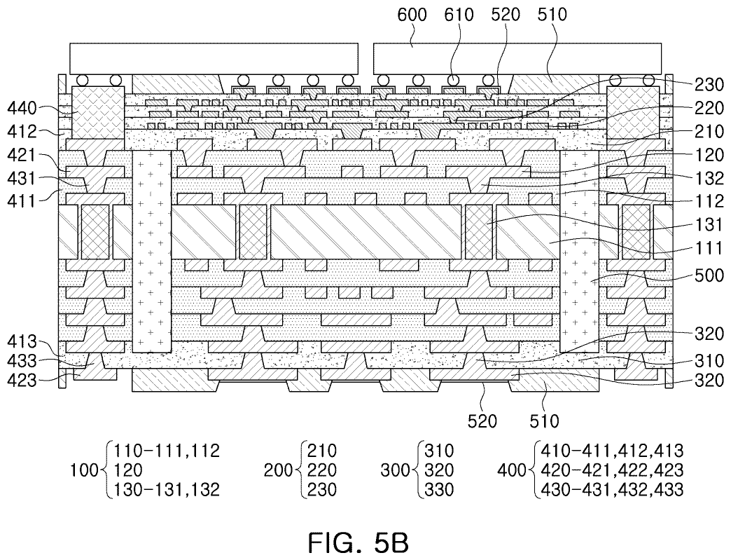

FIGS. 5A and 5B are schematic cross-sectional views illustrating a printed circuit board according to another example.

Referring to FIGS. 5A and 5B, in the printed circuit board according to another example, a fourth substrate portion 400 may further include a metal block 440. The metal block 440 may pass through a fourth-second insulating portion 412 to be connected to a fourth-first wiring layer 421. The metal block 440 may include a metal material. Any material having excellent thermal conductivity may be used as the metal material without limitation. Copper (Cu) may be preferably included, but the present disclosure is not limited thereto. An alloy including the above-described material may be used. The metal block 440 may have a rectangular column shape, but the present disclosure is not limited thereto, and may have various shapes such as a cylinder column shape and a polygonal column shape. In addition, the metal block 440 may have a pin-like shape. The metal block 440 may be formed using plating, but the present disclosure is not necessarily limited thereto. A method for forming the metal block 440 may not be limited, such as the metal block 440 formed by removing a portion of the fourth-second insulating portion 412, inserting the metal block 440 into the removed portion, and attaching the metal bock 440 to the fourth-second insulating portion 412, or the metal block inserted into the fourth-second insulating portion 412 to pass through the fourth-second insulating portion 412 as a rivet, and the like.

The metal block 440 may improve heat dissipation characteristics. As the metal block 440 is disposed on the fourth substrate portion 400, a metal of the fourth substrate portion 400, performing a heat dissipation function, may have a further increased area. That is, as the metal block 440 having excellent thermal conductivity is disposed on the fourth substrate portion 400, the printed circuit board according to another example may have excellent heat dissipation characteristics.

A component the same as those of the printed circuit board according to an example and/or the printed circuit board according to another example, among components other than the metal block 440 of the fourth substrate portion 400, may be applied to the printed circuit board according to another example, and thus a repeated description related thereto will be omitted.

### Method of Manufacturing Printed Circuit Board

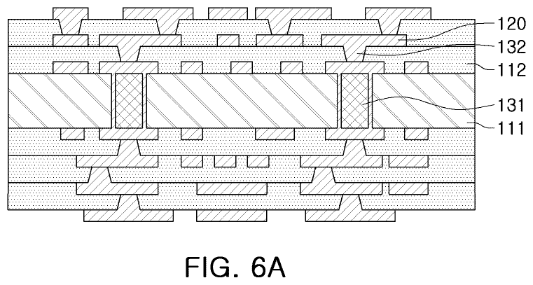

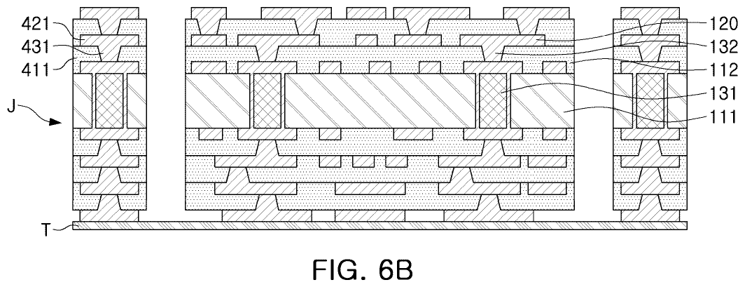

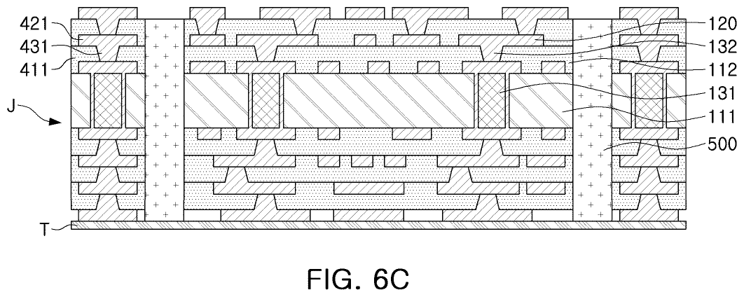

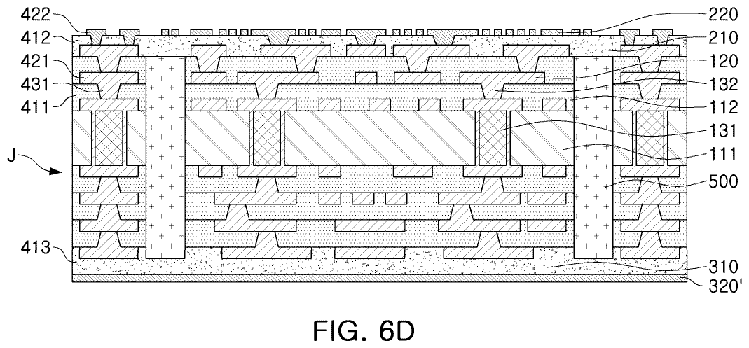

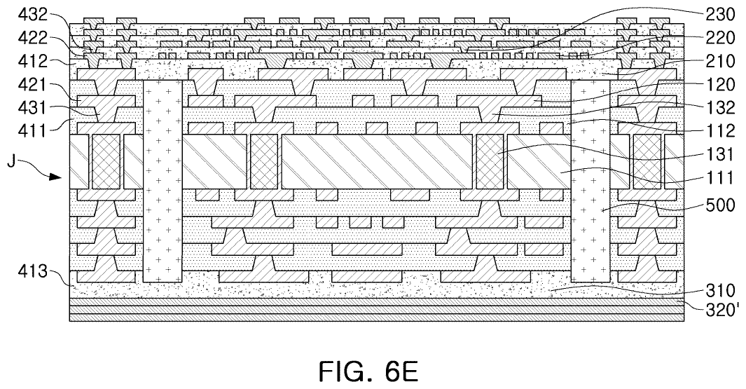

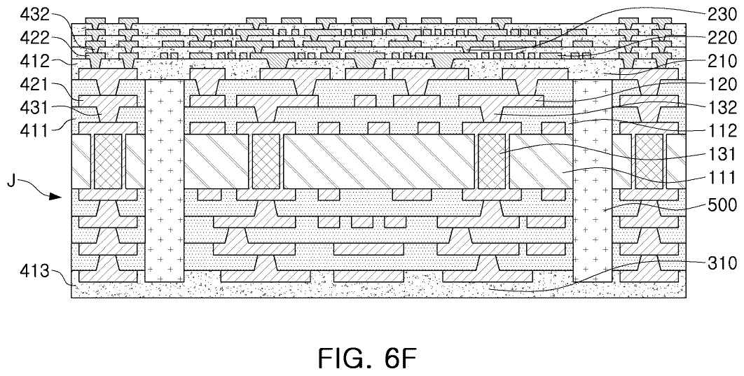

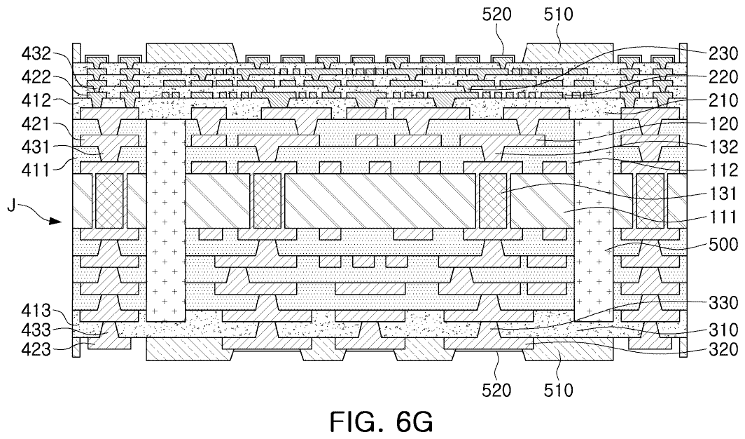

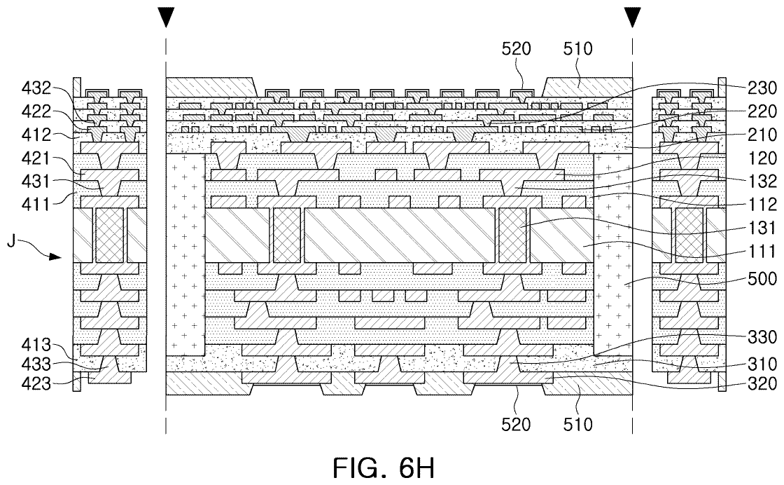

FIGS. 6A to 6H are cross-schematic cross-sectional views illustrating a method for manufacturing a printed circuit board according to an example.

Referring to FIG. 6A, a first substrate portion 100 may be prepared.

The first substrate portion 100 may be formed by applying any process that could be applied by those skilled in the art without limitation. The first substrate portion 100 may be manufactured in a unit of a strip and may then be subject to a singulation process through dicing or sawing, but the present disclosure is not necessarily limited thereto, and the first substrate portions 100 may be formed separately.

Referring to FIG. 6B, the first substrate portion 100 may be disposed in a jig J.

The jig J may be a means for fixing the first substrate portion 100. When an operation of forming the first substrate portion 100 is performed using a process of forming the first substrate portion 100 in a unit of a strip and then performing singulation thereon in a unit, the jig J may be a dummy region generated in the operation of forming the first substrate portion 100. When a defect inspection is performed on the first substrate portion 100 before an operation of disposing the first substrate portion 100 in the jig J, a manufacturing operation may no longer be performed on the defective first substrate portion 100. That is, a second substrate portion 200 may not be formed on the defective first substrate portion 100, thereby effectively reducing costs.

The jig J may be manufactured together in the operation of forming the first substrate portion 100, and thus may include a component corresponding to that of the first substrate portion 100. When the jig J is not removed in an operation to be described below, the jig J may correspond to a portion of a fourth substrate portion 400. That is, the jig J may correspond to a fourth-first insulating portion 411, a fourth-second wiring layer 422, and a fourth-third via layer 433 of the fourth substrate portion part 400.

The first substrate portion 100 may be coupled by attaching an adhesive member T to a lower surface of the jig J. A lower surface of the first substrate portion 100 and a lower surface of the jig J may be respectively attached and fixed by the adhesive member T. The adhesive member T may be a general tape, a die-attach film (DAF), or the like, and any means that could be used by those skilled in the art to temporarily fix a component may be used without limitation. In this case, a lowermost surface of a first wiring layer 120 of the first substrate portion 100 may be attached to the adhesive member T, but the present disclosure is not limited thereto.

Referring to FIG. 6C, a resin layer 500 may be filled between the first substrate portion 100 and the jig J.

The resin layer 500 may be filled with a flowable resin in an uncured state and then cured. As the resin layer 500 is disposed and cured between the first substrate portion 100 and the jig J, the first substrate portion 100 and the jig J may be fixed by the resin layer 500. In this case, the flowable resin layer 500 may be filled to cover a side surface of a first insulating portion 110 of the first substrate portion 100, and may cover a side surface of the jig J. As described above, the jig J may be a portion of the fourth substrate portion 400, that is, the resin layer 500 may cover a portion of a side surface of the fourth substrate portion 400.

The resin layer 500 may include a flowable material, such that an upper surface of the resin layer 500 may be substantially coplanar with an upper surface of the first insulating portion 110. However, the present disclosure is not limited thereto, and the upper surface of the resin layer 500 may be formed to protrude further than a portion of the first insulating portion 110. The resin layer 500 may be filled up to a surface on which the adhesive member T is present, such that a lower surface of the resin layer 500 may be substantially coplanar with a lower surface of the first wiring layer 120 of the first substrate portion 100. Although not illustrated in FIG. 6C, the resin layer 500 may be formed to fill a space between the adhesive member and the first wiring layer 120.

Referring to FIGS. 6D to 6F, after the adhesive member T is removed, a second substrate portion 200 and a third insulating portion 310 may be formed.

As the resin layer 500 fixes the first substrate portion 100 and the jig J, the first substrate portion 100, the resin layer 500, and the jig J may not be separated from each other even when the adhesive member T is removed. A second insulating portion 210 may be formed on the first insulating portion 110, and a third insulating portion 310 may be formed on a lower surface of the first insulating portion.

When the second substrate portion 200 is formed on the first substrate portion 100, a temporary layer 320′ may be additionally formed on a lower portion of the first substrate portion 100 to control warpage of the printed circuit board. That is, referring to FIG. 6D, warpage may be controlled by forming the third insulating portion 310 to correspond to the second insulating portion 210. Referring to FIGS. 6D and 6E, warpage may be controlled by forming the temporary layer 320′ to correspond to a second wiring layer 220. The temporary layer 320 may be formed using plating, and may be formed using a process the same as that of the second wiring layer 220, but may not be patterned. Referring to FIG. 6F, the temporary layer 320′ may be removed. Any method that could be used by those skilled in the art may be used as a method for removing the temporary layer 320′ without limitation.

When the second substrate portion 200 is formed on the first substrate portion 100, a fourth-second insulating portion 412, a fourth-second wiring layer 422, and a fourth-second via layer 432 may be further formed on the jig J, as necessary. As described above in connection with the printed circuit board according to another example, the fourth substrate portion 400 may perform a heat dissipation function. Thus, the fourth-second wiring layer 422 may be designed in an operation of forming the second substrate portion 200 such that the fourth substrate portion 400 performs a heat dissipation function.

The present disclosure is not limited thereto. When a last operation includes an operation of removing the jig J, another component may not be further formed on the jig J. That is, when the jig J is removed, another component may not be formed on the jig J, thereby reducing costs. In this case, the second substrate portion 200 may be disposed on the first substrate portion 100 to extend onto the resin layer 500, but may not extend onto the jig J.

The above description may be applied in the same manner even when the third insulating portion 310 is formed on a lower surface of the first substrate portion 100, and thus a repeated description will be omitted.

Referring to FIG. 6G, a third wiring layer 320 may be formed on the third insulating portion 310, and a third via layer 330, passing through the third insulating portion 310, may be formed. In addition, a solder resist layer 510 may be formed on the second insulating portion 210 and/or the third insulating portion 310, and a surface treatment layer may be formed on a portion of the second wiring layer 220 and the third wiring layer 320.

Referring to FIG. 6H, the printed circuit board according to an example may be completed by cutting along a boundary of the resin layer 500. In this case, a cut surface of each unit may not need to correspond to a boundary between the resin layer 500 and the jig J, and at least a portion of the resin layer 500 may be removed together. When the jig J remains to perform a heat dissipation function as the fourth substrate portion 400, the jig J may not be cut.

In addition, the printed circuit board according to an example may further include a general component of a printed circuit board. When the technical meaning of the present disclosure is not changed, additions or omissions may be freely made.

In the present disclosure, first and fourth substrate portions may refer to distinguish regions of a board from each other within a single printed circuit board. That is, the first and fourth substrate portions may not have clearly distinguished boundaries therebetween, and respective substrate portions may not need to be manufactured separately and coupled to each other.

In the present disclosure, the same insulating materials may refer to not only the exact same insulating materials, but also the same type of insulating materials. Thus, the same insulating materials may have substantially the same composition, but may have slightly different specific composition ratios.

In the present disclosure, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

In the present disclosure, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a first substrate portion including a first insulating portion and a plurality of first wiring layers respectively disposed on or in the first insulating portion;
a resin layer disposed to cover a side surface of the first insulating portion; and
a second substrate portion including a second insulating portion disposed to cover each of an upper surface of the first insulating portion and an upper surface of the resin layer, and a second wiring layer disposed on or in the second insulating portion.

2. The printed circuit board of claim 1, wherein the second wiring layer includes a wiring finer than a wiring of the first wiring layer.

3. The printed circuit board of claim 1, wherein the second insulating portion covers at least a portion of the first wiring layer.

4. The printed circuit board of claim 1, wherein a side surface of the second insulating portion is substantially coplanar with a side surface of the resin layer.

5. The printed circuit board of claim 1, wherein at least a portion of the second wiring layer is disposed on an upper region of the resin layer.

6. The printed circuit board of claim 1, further comprising:
a third substrate portion including a third insulating portion disposed on a lower side of the first insulating portion, and a third wiring layer disposed on the third insulating portion.

7. The printed circuit board of claim 6, wherein the third insulating portion covers a lower surface of the resin layer.

8. The printed circuit board of claim 6, wherein the third insulating portion includes a material substantially the same as a material of the second insulating portion.

9. The printed circuit board of claim 6, further comprising:
a solder resist layer disposed on each of the second insulating portion and the third insulating portion.

10. The printed circuit board of claim 9, wherein a side surface of the solder resist layer is substantially coplanar with a side surface of the second insulating portion and a side surface of the resin layer.

11. The printed circuit board of claim 6, further comprising:
a fourth substrate portion including a fourth insulating portion disposed on side surfaces of the second and third insulating portions and a side surface of the resin layer, and a fourth wiring layer disposed on or in the fourth insulating portion.

12. The printed circuit board of claim 11, wherein
the fourth insulating portion includes a fourth-first insulating portion and a fourth-second insulating portion,
the fourth-first insulating portion includes a material substantially the same as a material of the first insulating portion, and
the fourth-second insulating portion includes a material substantially the same as a material of the second insulating portion.

13. The printed circuit board of claim 12, wherein
the fourth wiring layer includes a fourth-first wiring layer and a fourth-second wiring layer,
the fourth-first wiring layer includes a wiring having a density substantially the same as that of a wiring of the first wiring layer, and
the fourth-second wiring layer includes a wiring having a density substantially the same as that of a wiring of the second wiring layer.

14. The printed circuit board of claim 12, wherein the fourth-second insulating portion and the second insulating portion are one integral insulating portion.

15. The printed circuit board of claim 11, wherein the fourth substrate portion includes a metal block passing through at least a portion of the fourth insulating portion, the metal block connected to the fourth wiring layer.

16. The printed circuit board of claim 1, wherein the resin layer includes at least one of a thermal interface material (TIM), a bonding sheet, an epoxy molding compound (EMC), or an underfill resin.

17. A printed circuit board comprising:
a first substrate portion including a first insulating portion and a first wiring layer disposed on or in the first insulating portion;
a resin layer disposed to cover a side surface of the first substrate portion; and
a second substrate portion including a second insulating portion disposed on the first insulating portion and the resin layer, and a second wiring layer disposed on or in the second insulating portion,
wherein an upper surface of the resin layer is substantially coplanar with an upper surface of the first insulating portion.

18. The printed circuit board of claim 17, wherein
a side surface of the resin layer is externally exposed, and
a side surface of the second insulating portion is substantially coplanar with the side surface of the resin layer.

19. A printed circuit board comprising:
a first substrate portion including a first insulating portion and a first wiring layer disposed on or in the first insulating portion;
a resin layer disposed to cover a side surface of the first substrate portion;
a second substrate portion including a second insulating portion disposed on the first insulating portion and the resin layer, and a second wiring layer disposed on or in the second insulating portion; and
a third substrate portion including a third insulating portion disposed on a lower side of the first insulating portion, and a third wiring layer disposed on the third insulating portion,
wherein a lower surface of the resin layer is substantially coplanar with a lower surface of the first wiring layer.

20. The printed circuit board of claim 19, wherein the second insulating portion and the third insulating portion are in contact with the resin layer.
